(19) United States
(12) Patent Application Publication
(10) Pub. No.: US 2026/0215074 A1
(43) Pub. Date: Jul. 23, 2026

(54) QUANTUM DOT SOLUTION, LIGHT-EMITTING ELEMENT, DISPLAY DEVICE, AND METHOD FOR FORMING LIGHT-EMITTING LAYER

(71) Applicant: Sharp Display Technology Corporation, Kameyama City, Mie (JP)

(72) Inventors: YASUSHI ASAOKA, Sakai City, Osaka (JP); Sentaro KIDA, Sakai City, Osaka (JP); Takahiro ADACHI, Sakai City, Osaka (JP)

(21) Appl. No.: 19/135,478

(22) PCT Filed: Dec. 6, 2022
(86) PCT No.: PCT/JP2022/044820

§ 371 Date: Jun. 4, 2025

(51) Int. Cl. H10K 50/115; C09K 11/56; H10K 59/00; H10K 59/12; H10K 71/13; H10K 71/20; H10K 71/40

(52) U.S. Cl. CPC H10K 50/115; C09K 11/56; H10K 59/1201; H10K 59/771; H10K 71/135; H10K 71/221; H10K 71/441; C09K 2211/188

(57) ABSTRACT

A quantum dot solution includes a plurality of quantum dots; a plurality of organic ligands other than a dithiocarboxylic acid; a plurality of metal sulfide precursors having a total mass equal to or smaller than a total mass of the plurality of quantum dots and the plurality of organic ligands; and a solvent.

### TECHNICAL FIELD

The present disclosure relates to a quantum dot solution, a light-emitting element, a display device, and a method for forming a light-emitting layer.

### BACKGROUND ART

In recent years, quantum-dot light-emitting diodes (QLEDs), which are light-emitting diodes including quantum dots, and display devices provided with QLEDs have attracted much attention because they can achieve low power consumption, slimming-down, high image quality, and other advantages. For this reason, studies have been conducted actively on a quantum dot solution for forming a light-emitting layer including quantum dots provided in QLEDs, and on a method for forming a light-emitting layer including quantum dots.

For instance, Patent Literature 1 describes forming a QLED light-emitting layer by forming a quantum dot layer firstly, followed by subjecting the quantum dot layer to an aftertreatment with a matrix member containing a metal chalcogenide.

### CITATION LIST

### Patent Literature

Patent Literature 1: United States Unexamined Patent Application Publication No. US 2021/0135138 A1

### SUMMARY OF INVENTION

### Technical Field

However, in the method for forming the QLED light-emitting layer described in Patent Literature 1, the QLED light-emitting layer is formed by forming a quantum dot layer firstly, followed by subjecting the quantum dot layer to an aftertreatment with a matrix member containing a metal chalcogenide. As such, the quantum dots inevitably deteriorate during the formation of the quantum dot layer; in particular, forming a quantum dot layer in the atmosphere considerably deteriorates the quantum dots, thus unfortunately deteriorating the emission characteristic of the light-emitting layer in QLEDs considerably.

In addition, the method for forming the QLED light-emitting layer described in Patent Literature 1 tends to produce a region where the matrix member cannot be filled from a dropping location of the matrix member containing the metal chalcogenide to a far site; in such a region, the quantum dots deteriorate considerably, thus unfortunately deteriorating the emission characteristic of the light-emitting layer in QLEDs.

In view of these problems, it is an object of one aspect of the present disclosure to provide a quantum dot solution, a light-emitting element, a display device, and a method for forming the light-emitting layer that can prevent quantum dot's deterioration, prevent reduction in the emission characteristic of the light-emitting layer, adjust the balance of carriers to be injected into the quantum dots, and improve the emission characteristic of the light-emitting layer.

### Solution to Problem

To solve the problems, a quantum dot solution in the present disclosure includes the following:
a plurality of quantum dots;
a plurality of organic ligands other than a dithiocarboxylic acid;
a plurality of metal sulfide precursors having a total mass equal to or smaller than the total mass of the plurality of quantum dots and the plurality of organic ligands; and
a solvent.

To solve the above problems, a light-emitting element in the present disclosure includes the following:
an anode;
a cathode; and
a light-emitting layer provided between the anode and the cathode.

The light-emitting layer includes a plurality of quantum dot units including the following: a plurality of first organic ligands; a plurality of second organic ligands; and a first quantum dot and a second quantum dot disposed adjacently in a second direction orthogonal to a first direction that is the thickness direction of the light-emitting layer.

Each of the plurality of quantum dot units disposed between a first surface facing the cathode of the light-emitting layer and a second surface facing the anode of the light-emitting layer includes a quantum-dot protection region including the plurality of first organic ligands closer to the first quantum dot than to the second quantum dot, the plurality of second organic ligands closer to the second quantum dot than to the first quantum dot, and a medium region provided at least between the plurality of first organic ligands and the plurality of second organic ligands, and containing an inorganic material.

To solve the above problems, a display device in the present disclosure includes the light-emitting element.

To solve the above problems, a method for forming a light-emitting layer in the present disclosure includes the following:
a first step of applying, onto a substrate in the atmosphere, a quantum dot solution containing a plurality of quantum dots, a plurality of organic ligands other than a dithiocarboxylic acid, a plurality of metal sulfide precursors, and a solvent, the plurality of metal sulfide precursors having a total mass equal to or smaller than the total mass of the plurality of quantum dots and the plurality of organic ligands; and
a second step of baking at a temperature equal to or higher than the decomposition temperature of the plurality of metal sulfide precursors in the atmosphere or under an inert gas atmosphere.

### Advantageous Effect of Invention

The aspects of the present disclosure can provide a quantum dot solution, a light-emitting element, a display device, and a method for forming the light-emitting layer that can prevent quantum dot's deterioration, prevent reduction in the emission characteristic of the light-emitting layer, adjust the balance of carriers to be injected into the quantum dots, and improve the emission characteristic of the light-emitting layer.

### BRIEF DESCRIPTION OF DRAWINGS

FIG. 1 is a schematic cross-sectional view of the schematic configuration of a light-emitting element according to a first embodiment.

FIG. 2 is a partial enlarged view of the schematic configuration of a light-emitting layer provided in the light-emitting element according to the first embodiment illustrated in FIG. 1.

FIG. 3 illustrates a region formed between two closely adjacent quantum dots among a plurality of quantum dots included in the light-emitting layer provided in the light-emitting element according to the first embodiment illustrated in FIG. 2.

FIG. 4 illustrates a region formed between two adjacent quantum dots with a small distance, among the plurality of quantum dots included in the light-emitting layer provided in the light-emitting element according to the first embodiment illustrated in FIG. 2.

FIG. 5 illustrates a method for forming the light-emitting layer provided in the light-emitting element according to the first embodiment illustrated in FIG. 1.

FIG. 6 is a graph showing the PL-t retention rate after 70 hours of respective light-emitting layers formed using quantum dot solutions having different QD concentrations.

FIG. 7 is a graph showing the relationship between the current density and standardized external quantum efficiency (EQE) of each of light-emitting elements including respective light-emitting layers formed using quantum dot solutions having different QD concentrations.

FIG. 8 is a graph showing the relationship between the QD concentration and EL emission voltage of each of light-emitting elements including respective light-emitting layers formed using quantum dot solutions having different QD concentrations.

FIG. 9 is a graph showing the relationship between the QD concentration and standardized maximum external quantum efficiency (standardized maximum EQE) of each of light-emitting elements including respective light-emitting layers formed using quantum dot solutions having different QD concentrations.

FIG. 10 is a graph showing the relationship between the voltage and current density of the light-emitting element according to the first embodiment illustrated in FIG. 1, and the relationship between the voltage and current density of a light-emitting element according to a comparative example including a light-emitting layer formed using a quantum dot solution containing no metal sulfide precursors.

FIG. 11 is a graph showing the relationship between the voltage and standardized external quantum efficiency (EQE) of the light-emitting element according to the first embodiment illustrated in FIG. 1, and the relationship between the voltage and standardized EQE of the light-emitting element according to the comparative example including the light-emitting layer formed using the quantum dot solution containing no metal sulfide precursors.

FIG. 12 shows the kinds and relative amounts of the constituent elements contained in a portion A of the light-emitting layer provided in the light-emitting element according to the first embodiment illustrated in FIG. 1.

FIG. 13 shows the kinds and relative amounts of the constituent elements contained in a portion B of the light-emitting layer provided in the light-emitting element according to the first embodiment illustrated in FIG. 1.

FIG. 14 is a table showing that in standardization at the signal intensity of Se1 shown in FIGS. 12 and 13, the signal intensities of Zn and S contained in the portion B of the light-emitting layer provided in the light-emitting element according to the first embodiment illustrated in FIG. 1 are larger than the signal intensities of Zn and S contained in the portion A of the light-emitting layer provided in the light-emitting element according to the first embodiment illustrated in FIG. 1.

FIG. 15 is a table showing that in standardization at the signal intensity of Se2 shown in FIGS. 12 and 13, the signal intensities of Zn and S contained in the portion B of the light-emitting layer provided in the light-emitting element according to the first embodiment illustrated in FIG. 1 are larger than the signal intensities of Zn and S contained in the portion A of the light-emitting layer provided in the light-emitting element according to the first embodiment illustrated in FIG. 1.

FIG. 16 is a schematic cross-sectional view of the schematic configuration of a display device according to a second embodiment.

FIG. 17 is a schematic cross-sectional view of the schematic configuration of a display device according to a third embodiment.

### DESCRIPTION OF EMBODIMENTS

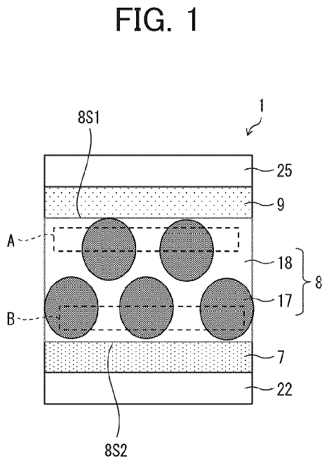

The following describes embodiments of the present disclosure with reference to FIGS. 1 to 17. Hereinafter, for convenience in description, a constituent having the same function as that of a constituent described in a particular embodiment will be denoted by the same sign, and its description will be omitted in some cases.

### First Embodiment

FIG. 1 is a schematic cross-sectional view of the schematic configuration of a light-emitting element 1 according to a first embodiment.

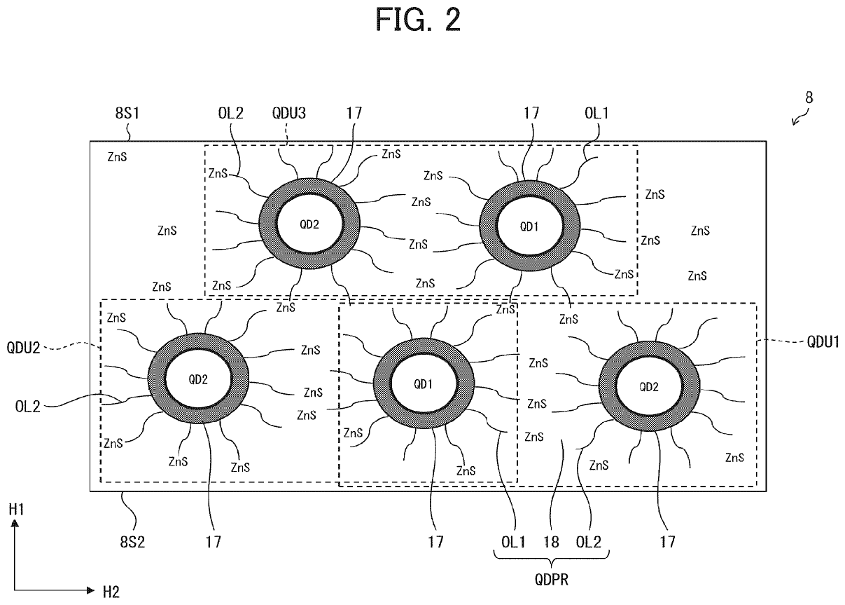

FIG. 2 is a partial enlarged view of the schematic configuration of a light-emitting layer 8 included in the light-emitting element 1 according to the first embodiment illustrated in FIG. 1.

As illustrated in FIG. 1, the light-emitting element 1 includes an anode 22, a cathode 25, and the light-emitting layer 8 provided between the anode 22 and the cathode 25. The light-emitting layer 8 includes a plurality of quantum dots 17, and a medium region 18 containing an inorganic material. The light-emitting layer 8 also includes a first surface 8S1 facing the cathode 25, and a second surface 8S2 facing the anode 22.

Although this embodiment describes, by way of example, a configuration where the light-emitting element 1 includes a hole transport layer as a hole functional layer 7 between the anode 22 and the light-emitting layer 8, and an electron transport layer as an electron functional layer 9 between the cathode 25 and the light-emitting layer 8, other configurations may be applied. For instance, the light-emitting element 1 may include, as the hole functional layer, at least one of a hole transport layer and a hole injection layer, and as the electron functional layer, at least one of an electron transport layer and an electron injection layer; alternatively, the light-emitting element 1 may not include at least one of the hole functional layer and electron functional layer.

As illustrated in FIG. 2, the light-emitting layer 8 includes a plurality of quantum dot units QDU1, QDU2, and QDU3 including the following: a plurality of first organic ligands OL1; a plurality of second organic ligands OL2; and a first quantum dot QD1 and a second quantum dot QD2 that are two quantum dots 17 adjacently disposed in a second direction H2 orthogonal to a first direction HI that is the thickness direction of the light-emitting layer 8. Each of the plurality of quantum dot units QDU1, QDU2, and QDU3 disposed between the first surface 8S1, which faces the cathode 25 of the light-emitting layer 8, and the second surface 8S2, which faces the anode 22 of the light-emitting layer 8, includes a quantum-dot protection region QDPR including the following: the plurality of first organic ligands OL1 closer to the first quantum dot QD1 than to the second quantum dot QD2; the plurality of second organic ligands OL2 closer to the second quantum dot QD2 than to the first quantum dot QD1; and the medium region 18 provided at least between the plurality of first organic ligands OL1 and the plurality of second organic ligands OL2, and containing an inorganic material.

The light-emitting element 1 includes the light-emitting layer 8 including the plurality of quantum dots 17 each protected by the quantum-dot protection region QDPR including the first organic ligands OL1, second organic ligands OL2 and medium region 18, can thus prevent the quantum dots 17 from deterioration and prevent the light-emitting layer 8 from reduction in emission characteristic.

Although this embodiment has described, by way of example, a configuration where the quantum dot unit QDU 3 is stacked on the quantum dot units QDU1 and QDU2 in the first direction HI, which is the thickness direction of the light-emitting layer 8, other configurations may be applied; for instance, the quantum dot units QDU1, QDU2, and QDU3 may not be stacked; alternatively, three or more quantum dot units QDU1, QDU2, and QDU3 may be stacked.

The quantum dots 17 each may have, for instance a core structure, a core-shell structure, a core-shell-shell structure, or a shell structure with the core ratio continuously varied. It is noted that the sell may cover the core completely or partly. In a mono-component system, the core portion can contain, for example, Si or C. In a binary system, the core portion can contain, for example, CdSe, CdS, CdTe, InP, GaP, InN, ZnSe, ZnS, or ZnTe. In a ternary system, the core portion can contain, for example, CdSeTe, GaInP, or ZnSeTe. In a quaternary system, the core portion can contain, for example, AgInGaS (AIGS). In a binary system, the shell portion can contain, for example, CdS, CdTe, CdSe, ZnS, ZnSe, or ZnTe. In a ternary system, the shell portion can contain, for example, CdSSe, CdTeSe, CdSTe, ZnSSe, ZnSTe, Zn TeSe, or AgInP (AIP).

It is noted that the quantum dots 17 are microparticles whose maximum width measures 100 nm or less. Each quantum dot 17 may each have any shape that satisfies this maximum width; the shape is not limited to a spherical tridimensional shape (circular cross-section shape). For instance, each quantum dot 17 may have a polygonal cross-section shape, a bar-shaped tridimensional shape, a branch-shaped tridimensional shape, a tridimensional shape having surface asperities, or a combination of them.

The quantum dots 17 may typically contain a semiconductor. The semiconductor may have a constant band gap. The semiconductor may be a material capable of emitting light. Moreover, at least the following materials may be contained. The semiconductor may be able to emit red, green, and blue light individually. The semiconductor contains, for example, at least one selected from the group consisting of a Group II-VI compound, a Group III-V compound, a chalcogenide, and a perovskite compound. It is also noted that a Group II-VI compound is a compound containing a Group II element and a Group VI element, and that a Group III-V compound is a compound containing a Group III element and a Group V element. It is also noted that Group II elements can include group 2 elements and group 12 elements, that Group III elements can include group 3 elements and group 13 elements, that Group V elements can include group 5 elements and group 15 elements, and that Group VI elements can include group 6 elements and group 16 elements.

The Group II-VI compound contains at least one selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe for instance.

The Group III-V compound contains at least one selected from the group consisting of GaAs, GaP, InN, InAs, InP, and InSb for instance.

The chalcogenide is a compound containing a group VI A(16) element; for instance, it contains CdS or CdSe. The chalcogenide may contain a mixed crystal of these materials.

The perovskite compound has a composition represented by the general formula CsPbX₃ for example. The constituent element X contains at least one selected from the group consisting of Cl, Br, and I for instance.

Here, the notation of element group numbers using Roman numerals is notation based on the former International Union of Pure and Applied Chemistry (IUPAC) system or the former Chemical Abstracts Service (CAS) system, and the notation of element group numbers using Arabic numerals is notation based on the current IUPAC system.

This embodiment describes, by way of example, an instance where each of the first organic ligands OL1 and second organic ligands OL2, which are organic ligands OL, are organic ligands other than dithiocarboxylic acids. It is noted that dithiocarboxylic acids are compounds that can be represented by RC(═S)SH, and that for instance, dithiocarboxylic acids include dithiocarbamate whose R is an amino group, or xanthogenic acids whose R is a hydroxy group or an alkoxy group.

This embodiments describes, by way of example, an instance where the inorganic material of the medium region 18 is ZnS, which is a metal sulfide. Examples of the metal sulfide include, but not limited to, a metal sulfide containing zinc (Zn) and sulfur(S) (e.g., ZnS), a metal sulfide containing zinc (Zn), tellurium (Te) and sulfur(S) (e.g., ZnTeS), a metal sulfide containing zinc (Zn), magnesium (Mg) and sulfur(S) (e.g., ZnMgS₂), a metal sulfide containing magnesium (Mg) and sulfur(S) (e.g., MgS), a metal sulfide containing gallium (Ga) and sulfur(S) (e.g., Ga₂S₃), a metal sulfide containing zinc (Zn), gallium (Ga) and sulfur(S) (e.g., ZnGa₂S₄), and a metal sulfide containing magnesium (Mg), gallium (Ga) and sulfur(S) (e.g., MgGa₂S₄).

The inorganic material of the medium region 18 may be, for example, a metal oxide; examples of the metal oxide include, but not limited to, a zinc oxide (e.g., ZnO), a titanium oxide (e.g., TiO₂), a tin oxide (e.g., SnO₂), a tungsten oxide (e.g., WO₃), a zirconium oxide (e.g., ZrO₂), and a silicon oxide (e.g., SiO₂).

Further, this embodiment describes, by way of example, an instance where the medium region 18 is amorphous. As described above, since the light-emitting layer 8 includes the first organic ligands OL1 and second organic ligands OL2, which are the organic ligands OL, it is preferable that heating (baking) for forming the medium region 18, which will be described later on, be performed at a relatively low temperature equal to or lower than the desorption temperature of the organic ligands OL. The metal sulfide (e.g., ZnS) of the medium region 18 becomes amorphous when heating (baking) is performed at a relatively low temperature equal to or lower than the desorption temperature of the organic ligands OL.

As illustrated in FIG. 2, each of the first quantum dot QD1 and second quantum dot QD2, which are two quantum dots disposed adjacently in the second direction H2, includes a core portion and a shell portion, and the inorganic material of the medium region 18 and the shell portion may contain an identical element. For example, the inorganic material of the medium region 18 may be a metal sulfide (e.g., ZnS), and the shell portion may be a metal sulfide (e.g., ZnS) as well.

Further, for example, like the case where the inorganic material of the medium region 18 is ZnS and where the shell portion is ZnSe, the inorganic material of the medium region 18 may contain a higher-period element than the element of the shell portion.

As illustrated in FIG. 2, the total mass of the plurality of first organic ligands OL1 and the plurality of second organic ligands OL2, which are a plurality of organic ligands OL included in the light-emitting layer 8, is preferably 10 to 50% inclusive of the total mass of a plurality of first quantum dots QD1 and a plurality of second quantum dots QD2, which are a plurality of quantum dots 17 included in the light-emitting layer 8. Such a configuration can effectively prevent agglomerates of the quantum dots 17, thus facilitating charge injection into the quantum dots.

As illustrated in FIG. 2, in one or more of the plurality of quantum dot units QDU1, QDU2, and QDU3 in the cross section of the light-emitting layer 8, the width of the medium region 18 in the second direction H2 of the light-emitting layer 8 is preferably smaller than the radius of the first quantum dot QD1, which is the quantum dot 17 and the radius of the second quantum dot QD2, which is the quantum dot 17, and is more desirably 4 to 12% inclusive of the radius of the first quantum dot QD1 or the radius of the second quantum dot QD2. Such a configuration can effectively protect the quantum dots 17 in the light-emitting layer 8 by the use of the quantum-dot protection region QDPR, which includes the plurality of first organic ligands OL1, the plurality of second organic ligands OL2, and the medium region 18, without forming the medium region 18 widely more than necessary. The configuration can also prevent the medium region 18 from hindering charge injection into the quantum dots QD.

As shown in FIG. 2, it is preferable that the medium regions 18 of one or more, which is herein the quantum dot unit QDU3, of the plurality of quantum dot units QDU1, QDU2, and QDU3 included in the light-emitting layer 8 constitute a part of the first surface 8S1 of the light-emitting layer 8, and that the medium regions 18 of another one or more, which is herein the quantum dot units QDU1 and QDU2, of the plurality of quantum dot units QDU1, QDU2, and QDU3 constitute a part of the second surface 8S2 of the light-emitting layer 8. In such a configuration, the medium regions 18 constitute a part of the first surface 8S1 or second surface 8S2 of the light-emitting layer 8, thereby enabling the quantum dots 17 to be protected effectively.

The medium region 18 may be a matrix. The matrix is a member containing and retaining another substance, and can be also referred to as a base, a base material, or a filler. The matrix may be a solid at room temperature. The matrix may be a member containing and retaining the quantum dots 17. The present disclosure encompasses an instance where the quantum dots 17 are not distributed in the matrix on average. Furthermore, some allowable matrix regions include no quantum dots 17.

A matrix of inorganic material maty be filled between the plurality of quantum dots 17. It is sufficient to know that the expression “a matrix of inorganic material is filled between the plurality of quantum dots 17” means that a matrix of inorganic material is filled at least between two quantum dots 17.

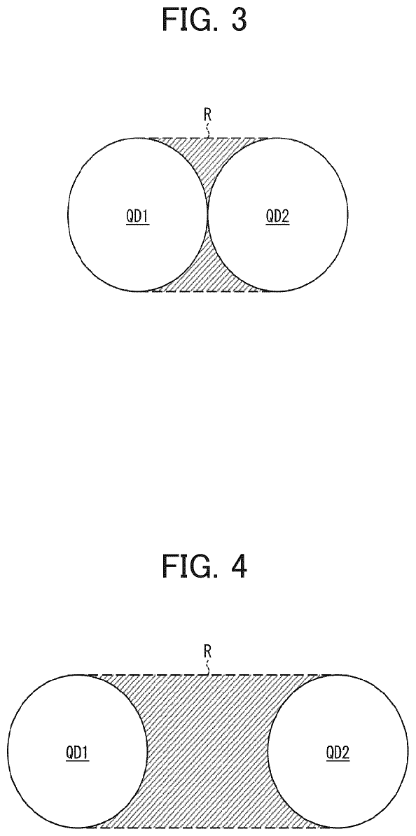

FIG. 3 illustrates a region R formed between the two closely adjacent quantum dots QD1 and QD2 among the plurality of quantum dots 17 included in the light-emitting layer 8 provided in the light-emitting element 1 according to the first embodiment illustrated in FIG. 2.

FIG. 4 illustrates the region R formed between the two adjacent quantum dots QD1 and QD2 with a small distance, among the plurality of quantum dots 17 included in the light-emitting layer 8 provided in the light-emitting element 1 according to the first embodiment illustrated in FIG. 2.

The region R illustrated in FIGS. 3 and 4 is a region surrounded by two straight lines (common outer tangent lines) circumscribing the perimeters of the two adjacent quantum dots QD1 and QD2, and by the perimeters of the two adjacent quantum dots QD1 and QD2. The region R is present in either case, i.e., whether the two adjacent quantum dots QD1 and QD2 are disposed closely as illustrated in FIG. 3, or disposed with a small distance as illustrated in FIG. 4, and the region R is filled with the inorganic material of the medium region 18. The expression “the inorganic material of the medium region 18 is filled between the two adjacent quantum dots QD1 and QD2” means that the region R illustrated in FIGS. 3 and 4 is filled or charged with the inorganic material of the medium region 18. It is noted that in the present disclosure, the two adjacent quantum dots QD1 and QD2 may be retained by the region R filled with the inorganic material of the medium region 18; for instance, at least a part of the region R may be filled with the inorganic material of the medium region 18.

This embodiment describes, by way of example, an instance where the region R, which is formed between the two adjacent quantum dots QD1 and QD2 illustrated in FIGS. 3 and 4, that is, the space between the plurality of quantum dots 17 is filled with the inorganic material of the medium region 18.

It is noted that the fact that the quantum dots QD1 and QD2 are retained by the inorganic material of the medium region 18 presenting in the region R, which is formed between the two adjacent quantum dots QD1 and QD2, means that at least a part of the region R is filled with the inorganic material of the medium region 18; this encompasses an instance where a part of the region R is filled with the inorganic material of the medium region 18, as well as an instance where the entire region R is filled with the inorganic material of the medium region 18.

The inorganic material of the medium region 18 may be formed so as to fill a region (space) other than the region including the plurality of quantum dots QD 17 in the light-emitting layer 8. Further, the inorganic material of the medium region 18 may constitute the outer edge of the light-emitting layer 8, and the plurality of quantum dots 17 may be formed so as to be located away from the outer edge. That is, the inorganic material of the medium region 18 may incorporate the plurality of quantum dots 17. Furthermore, at least a part of the outer edge of the light-emitting layer 8 may be formed by the inorganic material of the medium region 18 and the quantum dots 17. Further, each of the plurality of quantum dots 17 may be buried in the inorganic material of the medium region 18 at intervals. It is noted that the outer edge herein is the first surface 8S1 and second surface 8S2 of the light-emitting layer 8.

The inorganic material of the medium region 18 may include a continuous film. The continuous film is a film that cannot be divided by any material other than the materials of the continuous film. The continuous film may be an integral film being continuous without interruption through chemical bonding of the inorganic material of the medium region 18.

This embodiment describes a non-limiting instance where, as illustrated in FIG. 1, the light-emitting element 1 of conventional stacked structure includes the anode 22 and the cathode 25 positioned above the anode 22, wherein between the anode 22 and cathode 25, the hole functional layer 7, light-emitting layer 8, and electron functional layer 9, for instance, are stacked sequentially on the anode 22. For instance, the light-emitting element 1 may be a light-emitting element of reverse stacked structure; although not shown, such a light-emitting element of reverse stacked structure includes the cathode 25 and the anode 22 positioned above the cathode 25, wherein between the cathode 25 and anode 22, the electron functional layer 9, light-emitting layer 8, and hole functional layer 7, for instance, are stacked sequentially on the cathode 25.

Further, the light-emitting element 1 may be either a top-emission type or a bottom-emission type. To achieve a top-emission light-emitting element of conventional stacked structure, the anode 22 is formed using an electrode material that reflects visible light, and the cathode 25 is formed using an electrode material that transmits visible light. To achieve a bottom-emission light-emitting element of conventional stacked structure, the anode 22 is formed using an electrode material that transmits visible light, and the cathode 25 is formed using an electrode material that reflects visible light. On the other hand, to achieve a top-emission light-emitting element of reverse stacked structure, the cathode 25 is formed using an electrode material that reflects visible light, and the anode 22, which is above the cathode 25, is formed using an electrode material that transmits visible light. To achieve a bottom-emission light-emitting element of reverse stacked structure, the cathode 25 is formed using an electrode material that transmits visible light, and the anode 22, which is above the cathode 25, is formed using an electrode material that reflects visible light.

The electrode material that reflects visible light may be any material that can reflect visible light and is conductive; usable examples include, but not limited to, a metal material, such as Al, Mg, Li and Ag, an alloy of the metal material, a stack of the metal material and a transparent metal oxide (e.g., an indium tin oxide, an indium zinc oxide, and an indium gallium zinc oxide), and a stack of the alloy and transparent metal oxide.

On the other hand, the electrode material that transmits visible light may be any material that can transmit visible light and is conductive; examples include, but not limited to, a transparent metal oxide (e.g., an indium tin oxide, an indium zinc oxide, and an indium gallium zinc oxide), a thin film made of metal, such as Al or Ag, and a nanowire made of metal, such as Al or Ag.

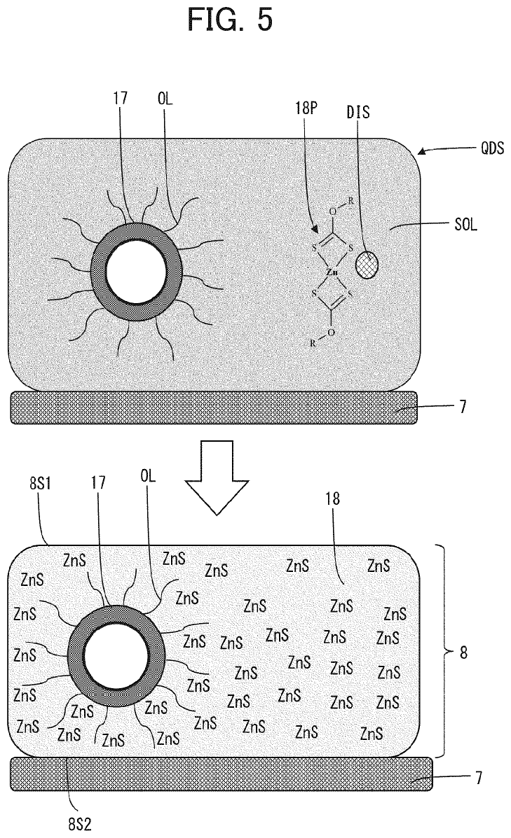

FIG. 5 illustrates a method for forming the light-emitting layer 8 provided in the light-emitting element 1 according to the first embodiment illustrated in FIG. 1.

As illustrated in FIG. 5, the method for forming the light-emitting layer 8 provided in the light-emitting element 1 according to the first embodiment illustrated in FIG. 1 includes the following: a first step (see the upper part of FIG. 5) of applying, onto a substrate, the hole functional layer 7 for instance, in the atmosphere, a quantum dot solution QDS containing a plurality of quantum dots 17, a plurality of organic ligands OL other than a dithiocarboxylic acid, a plurality of metal sulfide precursors 18P, and a solvent SOL, the plurality of metal sulfide precursors SOL having a total mass equal to or smaller than the total mass of the plurality of quantum dots 17 and the plurality of organic ligands OL; and a second step (see the lower part of FIG. 5) of heating (baking) at a temperature equal to or higher than the decomposition temperature of the plurality of metal sulfide precursors 18 in the atmosphere or under an inert gas atmosphere.

It is preferable that in the quantum dot solution QDS in a unit volume (e.g., 0.1 L), the total mass of the plurality of organic ligands OL be 10 to 50% inclusive of the total mass of the plurality of quantum dots 17. Doing so can prevent the light-emitting layer 8 from emission efficiency reduction resulting from the quantum dots 17 that include more organic ligands OL than necessary.

As the metal sulfide precursors 18P, metal sulfide precursors containing a dithiocarboxylic acid and a metal element may be used; for example, zinc xanthate or zinc dithiocarboxylate may be used. This embodiment describes, by way of example, an instance where zinc ethylxanthate (the R group illustrated in FIG. 5 is an ethyl group) is used.

The solvent SOL may be one or more selected from the group consisting of haloarenes in which a part of benzene's hydrogen is substituted with a halogen, and alkanes having 5 to 17 carbon atoms inclusive; alternatively, the solvent SOL may be a low-polarity solvent in which the square root of the square sum of the dipole term (SP) and hydrogen bond term (8H) of the Hansen solubility parameter is 8.3 or less. Among haloarenes, chlorobenzene, dichlorobenzene, iodobenzene, bromobenzene, and chlorotoluene for instance can be preferably used. Among alkanes having 5 to 17 carbon atoms inclusive, decane or octane for instance can be preferably used. Further, the solvent SOL preferably has a flash point of 40° C. or higher. This embodiment describes, by way of example, using, as the solvent SOL, a mixed solvent of octane and chlorobenzene, which is a low-polarity solvent in which the square root of the square sum of the dipole term (SP) and hydrogen bond term (8H) of the Hansen solubility parameter is 8.3 or less.

It is noted that for instance, a drying step of removing the solvent SOL at a temperature equal to or lower than the decomposition temperature of the metal sulfide precursors 18P may be performed between the first and second steps.

In this embodiment, since the quantum dot solution QDS contains the plurality of organic ligands OL other than a dithiocarboxylic acid, it is preferable in the second step of heating (baking) at a temperature equal to or higher than the decomposition temperature of the metal sulfide precursors 18P, and equal to or lower than the desorption temperature of the organic ligands OL; for example, the heating (baking) can be performed at, but not limited to, 110 to 200° C. inclusive. In this case, it is preferable to select such a kind of the organic ligands OL that the desorption temperature of the organic ligands OL is higher than, for instance, the decomposition temperature of zinc ethylxanthate, which is used as the metal sulfide precursors 18P in this embodiment; for instance, an organic ligand, such as dodecanethiol, can be used suitably.

Further, in this embodiment, zinc ethylxanthate is used as the metal sulfide precursors 18P, and a mixed solvent of octane and chlorobenzene is used as the solvent SOL; as such, a dispersant DIS is added to ensure the dispersibility of the metal sulfide precursors 18P in the solvent SOL.

Usable examples of the dispersant DIS to be added include an amine and a pyridine; the amine may include at least one of an amine containing a liner chain, and an amine containing a branched chain. This embodiment describes, by way of example, an instance where the dispersant DIS to be added is n-octylamine, which is an example amine containing a liner chain. Preferable usable example amines containing a branched chain include, but not limited to, octylamine, 6-undecaneamine, 2-hexyldecan-1-amine, and heptadecan-9-amine all having a boiling point of 180° C. or less.

In this embodiment, since the dispersant DIS is partially or entirely removed through heating (baking), as will be described later on, the quantum dot solution QDS illustrated in FIG. 5 contains the dispersant DIS having a mass smaller than the total mass of the plurality of metal sulfide precursors 18P per unit volume (e.g., 0.1 L). When the quantum dot solution QDS contains the dispersant DIS as described above, it is preferable to perform heating (baking) at a temperature equal to or higher than the decomposition temperature of the metal sulfide precursors 18P, and equal to or higher than a temperature at which at least a part of the dispersant DIS is vaporized. Removing at least a part of the dispersant DIS through heating (baking) in the above manner can reduce the influence of the dispersant DIS on the light-emitting layer 8. It is preferable in this case to use the dispersant DIS having a lower boiling point than the desorption temperature of the organic ligands OL; for instance, it is preferable to use the dispersant DIS having a boiling point of 150° C. or lower; pyridine, which has a relatively low boiling point, or amines, which have a relatively low boiling point, can be used suitably.

It is noted that when, for instance, metal sulfide precursors containing a long-chain dithiocarboxylic acid and a metal element are used as the metal sulfide precursors 18, the dispersant DIS does not have to be added, because the dispersibility of the metal sulfide precursors 18P in the solvent SOL can be ensured by a long-chain amino group or long-chain alkoxy group.

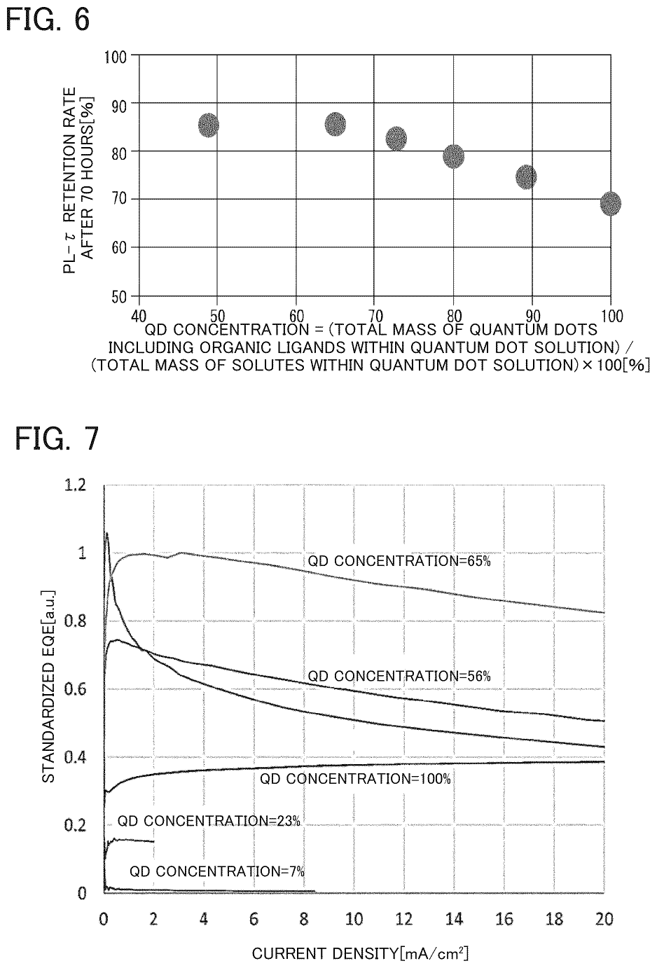

FIG. 6 is a graph showing the PL-t retention rate after 70 hours of respective light-emitting layers formed using quantum dot solutions having different QD concentrations.

The QD concentrations shown in FIG. 6 are values calculated by (the total mass of the quantum dots 17 including the organic ligands OL within the quantum dot solution QDS)/(the total mass of the solutes within the quantum dot solution QDS)×100 [%]. Here, the “total mass of the quantum dots 17 including the organic ligands OL within the quantum dot solution QDS” is the total mass of the mass of the plurality of organic ligands OL and the mass of the plurality of quantum dots 17; in such a case as that in this embodiment, where the quantum dot solution QDS contains the dispersant DIS, the “total mass of the solutes within the quantum dot solution QDS” is the total mass of the mass of the plurality of organic ligands OL, the mass of the plurality of quantum dots 17, the mass of the plurality of metal sulfide precursors 18P, and the mass of the dispersant DIS. It is noted that when the quantum dot solution QDS contains no dispersant DIS, the “total mass of the solutes within the quantum dot solution QDS” is the total mass of the mass of the plurality of organic ligands OL, the mass of the plurality of quantum dots 17, and the mass of the plurality of metal sulfide precursors 18P.

It is noted that the QD concentration herein was adjusted by fixing, for example, at about 0.72, the molar ratio ((the mass of zinc ethylxanthate/the molecular weight of zinc ethylxanthate)/(the mass of n-octylamine/the molecular weight of n-octylamine)) of the metal sulfide precursors 18P (zinc ethylxanthate having a molecular weight of 307.76) and dispersant DIS (n-octylamine having a molecular weight of 129.25) within the quantum dot solution QDS, and by changing the amount of addition of the quantum dots 17 including the organic ligand OL into the quantum dot solution QDS, the amount of addition of the metal sulfide precursors 18P into the quantum dot solution QDS, and the amount of addition of the dispersant DIS into the quantum dot solution QDS.

Table 1 below shows the total mass of the quantum dots 17 including the organic ligands OL, the total mass of the metal sulfide precursors 18P, and the total mass of the dispersants DIS, within quantum dot solutions QDS in a unit volume (e.g., 0.1 L) whose respective QD concentrations are 89%, 80%, 73%, 65%, 56%, 49%, and 39%. Table 1 also shows (the total mass of the quantum dots 17 including the organic ligands OL)/(the total mass of the metal sulfide precursors 18P), and (the total mass of the inorganic components within the metal sulfide precursors)/(the total mass of the quantum dots 17 including the organic ligands OL). It is noted that the quantum dot solutions in a unit volume (e.g., 0.1 L) whose respective QD concentrations are 23% and 7% in Table 1 below are comparative examples. For instance, the quantum dot solution QDS in 0.2 L whose volume doubles the foregoing unit volume (e.g., 0.1 L) contains the quantum dots 17 including the organic ligands OL, as well as the metal sulfide precursors 18P, the dispersant DIS, and the solvent SOL each of which has a total mass or a mass doubling that of these substances contained in the quantum dot solution QDS in the foregoing unit (e.g., 0.1 L).

TABLE 1

| | | | | | (TOTAL MASS OF |
|---|---|---|---|---|---|
| | | | | (TOTAL MASS | INORGANIC |
| | | | | OF QDs | COMPONENTS |
| | | | | INCLUDING | WITHIN METAL |
| | | | | ORGANIC | SULFIDE |
| | | TOTAL MASS | | LIGANDS)/ | PRECURSORS)/ |
| QD | | OF METAL | TOTAL MASS | (TOTAL MASS | (TOTAL MASS OF |
| CONCEN- | TOTAL MASS OF | SULFIDE | OF | OF METAL | QDs INCLUDING |
| TRATION | QDs INCLUDING | PRECURSORS | DISPERSANTS | SULFIDE | ORGANIC |
| [%] | ORGANIC LIGANDS | [g] | [g] | PRECURSORS) | LIGANDS) |
| 89 | 0.891 | 0.069 | 0.040 | 12.9 | 0.05 |
| 80 | 0.803 | 0.124 | 0.072 | 6.5 | 0.09 |
| 73 | 0.731 | 0.170 | 0.099 | 4.3 | 0.14 |
| 65 | 0.654 | 0.218 | 0.128 | 3.0 | 0.21 |
| 56 | 0.557 | 0.280 | 0.163 | 2.0 | 0.30 |
| 49 | 0.488 | 0.323 | 0.189 | 1.5 | 0.40 |
| 39 | 0.387 | 0.387 | 0.226 | 1.0 | 0.63 |
| 23 | 0.234 | 0.484 | 0.282 | 0.5 | 1.30 |
| 7 | 0.070 | 0.588 | 0.342 | 0.1 | 5.28 |

The quantum dot solution shown in FIG. 6 with a 100% QD concentration contains no metal sulfide precursors 18P and no dispersant DIS; thus, the total mass of the quantum dots 17 including the organic ligands OL within the quantum dot solution QDS is the same as the total mass of the solutes within the quantum dot solution QDS.

Table 1 reveals that in the case of the quantum dot solution shown in FIG. 6 with a 89% QD concentration, the quantum dot solution shown in FIG. 6 with a 80% QD concentration, the quantum dot solution shown in FIG. 6 with a 73% QD concentration, the quantum dot solution shown in FIG. 6 with a 65% QD concentration, and the quantum dot solution shown in FIG. 6 with a 49% QD concentration, the total mass of the quantum dots 17 including the organic ligands OL decreases in the stated order, and the volumes of the metal sulfide precursors 18P and dispersants DIS increase in the stated order.

The results of the PL-t retention rate after 70 hours of the respective light-emitting layers formed using the quantum dot solutions having different QD concentrations shown in FIG. 6 are each a PL-t change under the lightproof atmosphere measured on a light-emitting layer formed through the first step, i.e., forming quantum dot solutions onto a substrate, the hole functional layer 7 for instance, in the atmosphere by using quantum dot solutions having different QD concentrations, and then through drying the solvent SOL in the atmosphere at a temperature equal to or lower than the decomposition temperature of the metal sulfide precursors 18P. As earlier described, the value of the fluorescence lifetime after 25 minutes from the formation of the light-emitting layer is set as an initial value, and the result of an evaluation on the retention rate of the fluorescence lifetime after a predetermined elapsed time, with respect to the initial value.

FIG. 6 reveals that the light-emitting layers formed using the quantum dot solution with a 89% QD concentration containing the metal sulfide precursors 18P, the quantum dot solution with a 80% QD concentration containing the metal sulfide precursors 18P, the quantum dot solution with a 73% QD concentration containing the metal sulfide precursors 18P, the quantum dot solution with a 65% QD concentration containing the metal sulfide precursors 18P, and the quantum dot solution with a 49% QD concentration containing the metal sulfide precursors 18P have higher PL-t retention rates after 70 hours than the light-emitting layer formed using the quantum dot solution with a 100% QD concentration containing no metal sulfide precursors 18P. The light-emitting layer formed, in the film formation step in the atmosphere, by using the quantum dot solution with a 100% QD concentration containing no metal sulfide precursors 18P is susceptible to deterioration resulting from oxygen, water, and other factors when its quantum dots 17 are exposed to the atmosphere, because no metal sulfide precursors 18P (zinc ethylxanthate) are contained. On the other hand, the light-emitting layers formed, in the film formation step in the atmosphere, by using the quantum dot solution with a 89% QD concentration containing the metal sulfide precursors 18P (zinc ethylxanthate), the quantum dot solution with a 80% QD concentration containing the metal sulfide precursors 18P (zinc ethylxanthate), the quantum dot solution with a 73% QD concentration containing the metal sulfide precursors 18P (zinc ethylxanthate), the quantum dot solution with a 65% QD concentration containing the metal sulfide precursors 18P (zinc ethylxanthate), and the quantum dot solution with a 49% QD concentration containing the metal sulfide precursors 18P (zinc ethylxanthate) can improve resistance against exposure to the atmosphere because the metal sulfide precursors 18P (zinc ethylxanthate) block oxygen and water when their quantum dots are exposed to the atmosphere.

As shown in FIG. 6, at a QD concentration of 89% or less, the PL-t retention rate after 70 hours exhibits a favorable result, which is about 70% or more. That is, the PL-t retention rate after 70 hours exhibits a favorable result, which is about 70% or more, when the total mass of the plurality of quantum dots 17 and the plurality of organic ligands OL is 12.9 times or less of the total mass of the plurality of metal sulfide precursors 18P (see Table 1 above).

Further, it is preferable that in the quantum dot solution QDS in the foregoing unit volume (e.g., 0.1 L), the total mass of the inorganic components (e.g., zinc and sulfur) within the plurality of metal sulfide precursors 18P be 5% or more of the total mass of the plurality of quantum dots 17 and the plurality of organic ligands OL. It is noted that as earlier described, the mass of the plurality of metal sulfide precursors 18P decreases about 20 to 35% after the second step, i.e., heating (baking) at a temperature equal to or higher than the decomposition temperature of the metal sulfide precursors 18P.

FIG. 7 is a graph showing the relationship between the current density and standardized external quantum efficiency (EQE) of each of light-emitting elements including respective light-emitting layers formed using quantum dot solutions having different QD concentrations.

FIG. 7 reveals that the light-emitting elements including the respective light-emitting layers formed using the quantum dot solution with a 65% QD concentration containing the metal sulfide precursors 18P and dispersant DIS, the quantum dot solution with a 56% QD concentration containing the metal sulfide precursors 18P and dispersant DIS, the quantum dot solution with a 39% QD concentration containing the metal sulfide precursors 18P and dispersant DIS exhibit more favorable external quantum efficiency (EQE) than the light-emitting element including the light-emitting layer formed using the quantum dot solution with a 100% QD concentration containing no metal sulfide precursors 18P. In particular, FIG. 7 reveals that the external quantum efficiency (EQE) is the most favorable at the 65% QD concentration. This is because that the quantum dots (QDs), when exposed to the atmosphere during the film formation in the atmosphere, is protected from oxygen and water by the metal sulfide precursors 18P (zinc ethylxanthate), to thus achieve improved resistance against exposure to the atmosphere, and that after the film formation, the quantum-dot protection region QDPR including the plurality of organic ligands OL and medium region 18 reduces the influence of carrier injection hindrance.

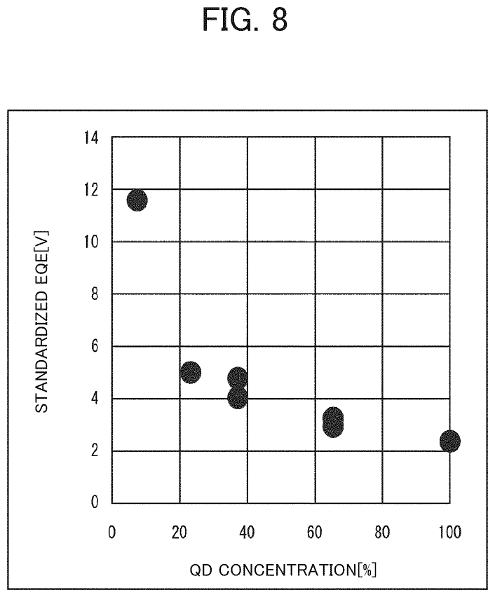

FIG. 8 is a graph showing the relationship between the QD concentration and EL emission voltage of each of light-emitting elements including respective light-emitting layers formed using quantum dot solutions having different QD concentrations.

As shown in FIG. 8, the EL emission voltage tends to rise when the QD concentration decreases; thus, to ensure favorable resistance against exposure to the atmosphere, and prevent rise in the EL emission voltage, it is preferable that the total mass of the plurality of quantum dots 17 and the plurality of organic ligands OL be 1.0 to 12.9 times inclusive of the total mass of the plurality of metal sulfide precursors 18P; that is, it is preferable that the QD concentration be 39 to 89% inclusive (see Table 1 above). It is preferable that in the quantum dot solution QDS in the foregoing unit volume, the total mass of the inorganic components (e.g., zinc and sulfur) within the plurality of metal sulfide precursors 18P be 5 to 63% inclusive of the total mass of the plurality of quantum dots 17 and the plurality of organic ligands OL (see Table 1 above).

In the quantum dot solution QDS in the foregoing unit volume, the total mass of the metal elements within the plurality of metal sulfide precursors 18P may be 5 to 20% inclusive of the total mass of the plurality of quantum dots 17 and the plurality of organic ligands OL.

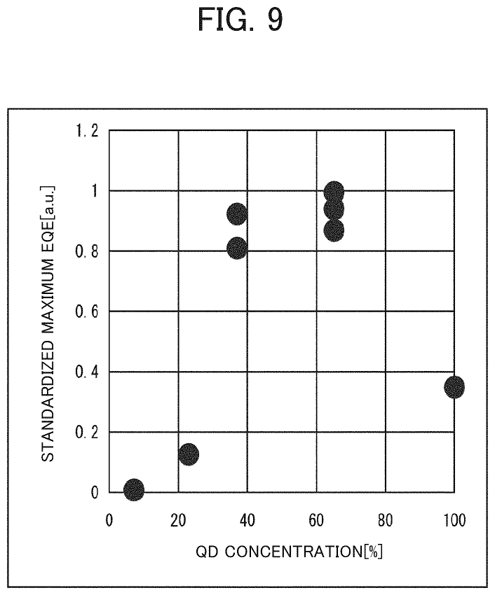

FIG. 9 is a graph showing the relationship between the QD concentration and standardized maximum external quantum efficiency (standardized maximum EQE) of each of light-emitting elements including respective light-emitting layers formed using quantum dot solutions having different QD concentrations.

As shown in FIG. 9, the maximum external quantum efficiency (maximum EQE) tends to lower when the QD concentration decreases; thus, to ensure favorable resistance against exposure to the atmosphere, and favorable maximum external quantum efficiency (maximum EQE), it is preferable that the total mass of the quantum dots 17 and the plurality of organic ligands OL be 1.0 to 12.9 times inclusive of the total mass of the plurality of metal sulfide precursors 18P; that is, it is preferable that the QD concentration be 39 to 89% inclusive. It is preferable that in the quantum dot solution QDS in the foregoing unit volume, the total mass of the inorganic components (e.g., zinc and sulfur) within the plurality of metal sulfide precursors 18P be 5 to 63% inclusive of the total mass of the plurality of quantum dots 17 and the plurality of organic ligands OL.

In the quantum dot solution QDS in the foregoing unit volume, the total mass of the metal elements within the plurality of metal sulfide precursors 18P may be 5 to 20% inclusive of the total mass of the plurality of quantum dots 17 and the plurality of organic ligands OL.

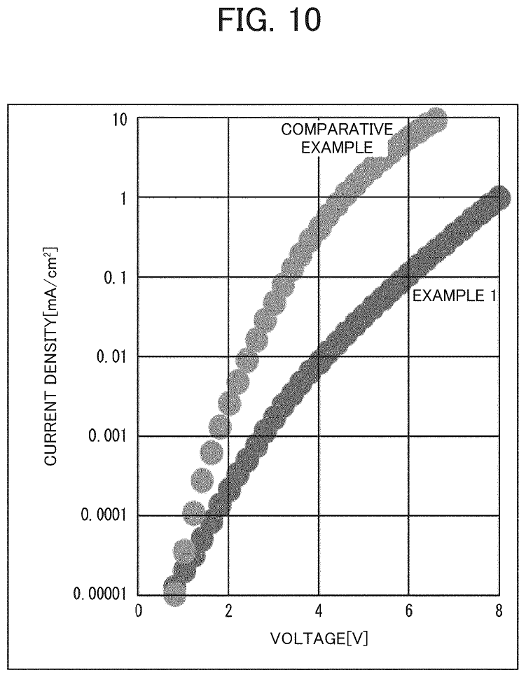

FIG. 10 is a graph showing the relationship between the voltage and current density of the light-emitting element 1 according to the first embodiment illustrated in FIG. 1, and the relationship between the voltage and current density of a light-emitting element according to a comparative example including a light-emitting layer formed using a quantum dot solution containing no metal sulfide precursors 18P.

As shown in FIG. 10, the light-emitting element 1 (Example 1 in FIG. 10), which includes the light-emitting layer 8 formed using the quantum dot solution containing the metal sulfide precursors 18P, has a larger voltage for obtaining the same current density, but exhibits a relatively smaller voltage rise than the light-emitting element according to the comparative example, which includes the light-emitting layer formed using the quantum dot solution containing no metal sulfide precursors 18P. This is because that the light-emitting layer 8 in the light-emitting element 1 includes the medium region 18 containing an appropriately regulated amount of metal sulfide (e.g., ZnS), so that the distance between the quantum dots 17 is kept relatively small to prevent voltage rise.

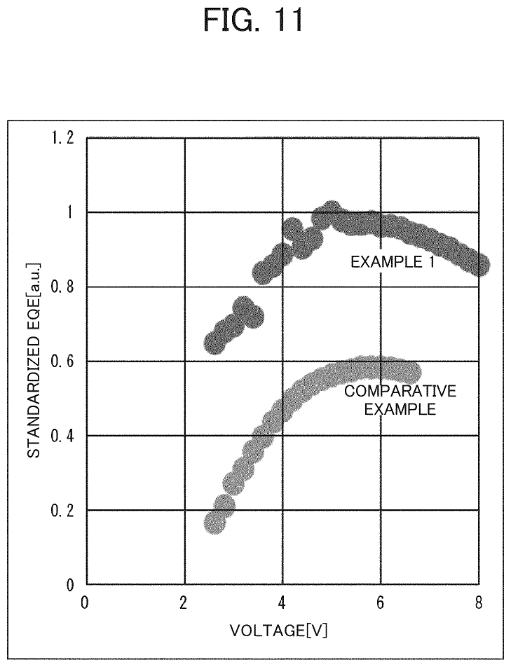

FIG. 11 is a graph showing the relationship between the voltage and standardized external quantum efficiency (standardized EQE) of the light-emitting element 1 according to the first embodiment illustrated in FIG. 1, and the relationship between the voltage and standardized EQE of the light-emitting element according to the comparative example including the light-emitting layer formed using the quantum dot solution containing no metal sulfide precursors 18P.

As shown in FIG. 11, the light-emitting element 1 (Example 1 in FIG. 11), which includes the light-emitting layer 8 formed using the quantum dot solution containing the metal sulfide precursors 18P, can achieve higher external quantum efficiency upon application of the same voltage, than the light-emitting element according to the comparative example, which includes the light-emitting layer formed using the quantum dot solution containing no metal sulfide precursors 18P. This is because that the light-emitting layer 8 in the light-emitting element 1 includes the medium region 18P including the quantum dots 17 prevented from deterioration during the film formation in the atmosphere, and further containing metal sulfides (e.g., ZnS), thereby preventing unnecessary current flowing between the quantum dots 17, so that high external quantum efficiency (EQE) can be achieved upon application of the same voltage.

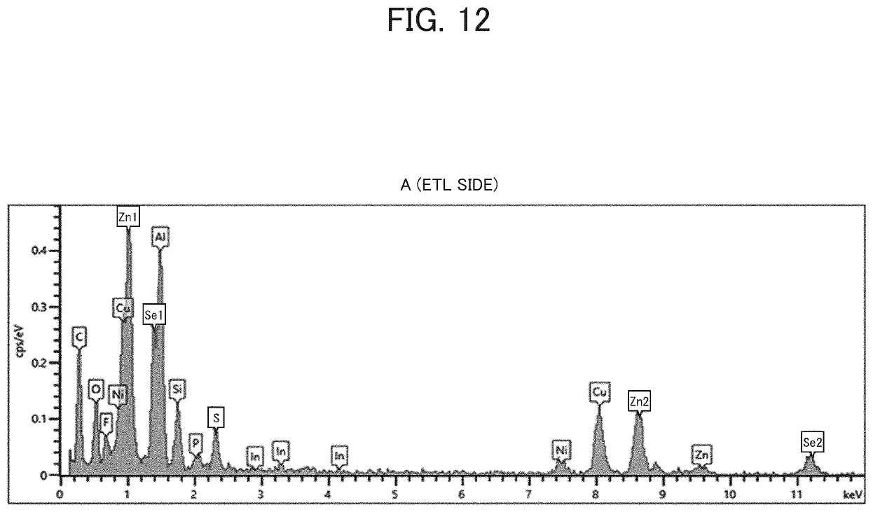

FIG. 12 shows the kinds and relative amounts of the constituent elements contained in a portion A of the light-emitting layer 8 provided in the light-emitting element 1 according to the first embodiment illustrated in FIG. 1.

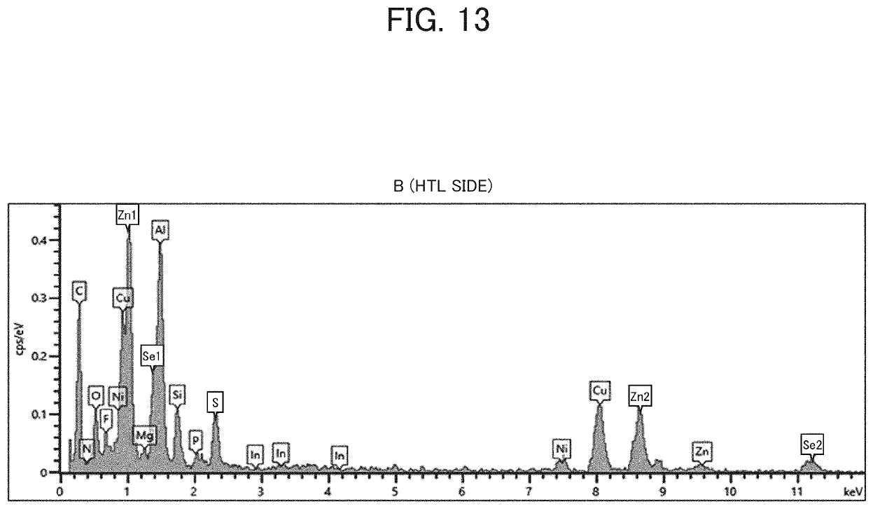

FIG. 13 shows the kinds and relative amounts of the constituent elements contained in a portion B of the light-emitting layer 8 provided in the light-emitting element 1 according to the first embodiment illustrated in FIG. 1.

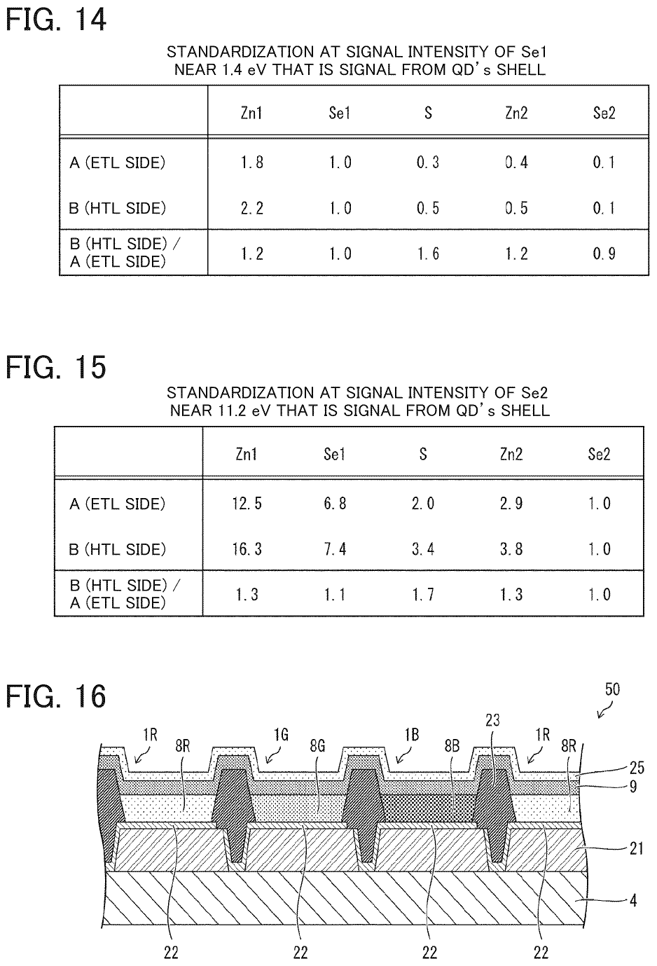

FIG. 14 is a table showing that in standardization at the signal intensity of Se1 shown in FIGS. 12 and 13, the signal intensities of Zn and S contained in the portion B of the light-emitting layer 8, which is provided in the light-emitting element 1 according to the first embodiment illustrated in FIG. 1, are larger than the signal intensities of Zn and S contained in the portion A of the light-emitting layer 8, which is provided in the light-emitting element according to the first embodiment illustrated in FIG. 1.

FIG. 15 is a table showing that in standardization at the signal intensity of Se2 shown in FIGS. 12 and 13, the signal intensities of Zn and S contained in the portion B of the light-emitting layer 8, which is provided in the light-emitting element 1 according to the first embodiment illustrated in FIG. 1, are larger than the signal intensities of Zn and S contained in the portion A of the light-emitting layer 8, which is provided in the light-emitting element according to the first embodiment illustrated in FIG. 1.

As shown in FIG. 14, in standardization at the signal intensity of Se1 shown in FIGS. 12 and 13, the signal intensities of Zn and S contained in the portion B of the light-emitting layer 8, which is provided in the light-emitting element 1 according to the first embodiment illustrated in FIG. 1, are larger than the signal intensities of Zn and S contained in the portion A of the light-emitting layer 8, which is provided in the light-emitting element according to the first embodiment illustrated in FIG. 1. Here, the portion B is a first region in the cross section of the light-emitting layer 8 that is a region closer to the hole functional layer 7 than to the electron functional layer 9, and the portion A is a second region in the cross section of the light-emitting layer 8 that is a region closer to the electron functional layer 9 than to the hole functional layer 7. The signal intensity of Zn in the portion B of the light-emitting layer 8 is 1.2 times as high as the signal intensity of Zn in the portion A of the light-emitting layer 8, and the signal intensity of S in the portion B of the light-emitting layer 8 is 1.6 times as high as the signal intensity of S in the portion A of the light-emitting layer 8. Such a difference in signal intensity means that the medium region 18 containing metal sulfide (e.g., ZnS) is formed wider in the portion B of the light-emitting layer 8 than in the portion A of the light-emitting layer 8.

As shown in FIG. 15, in standardization at the signal intensity of Se2 shown in FIGS. 12 and 13, the signal intensities of Zn and S contained in the portion B of the light-emitting layer 8, which is provided in the light-emitting element 1 according to the first embodiment illustrated in FIG. 1, are larger than the signal intensities of Zn and S contained in the portion A of the light-emitting layer 8, which is provided in the light-emitting element according to the first embodiment illustrated in FIG. 1. Here, the portion B is the first region in the cross section of the light-emitting layer 8, which is a region closer to the hole functional layer 7 than to the electron functional layer 9, and the portion A is the second region in the cross section of the light-emitting layer 8, which is a region closer to the electron functional layer 9 than to the hole functional layer 7. The signal intensity of Zn in the portion B of the light-emitting layer 8 is 1.3 times as high as the signal intensity of Zn in the portion A of the light-emitting layer 8, and the signal intensity of S in the portion B of the light-emitting layer 8 is 1.7 times as high as the signal intensity of S in the portion A of the light-emitting layer 8. Such a difference in signal intensity means that the medium region 18 containing metal sulfide (e.g., ZnS) is formed wider in the portion B of the light-emitting layer 8 than in the portion A of the light-emitting layer 8.

The foregoing has described, by way of example, an instance where the light-emitting element 1 is a light-emitting element of conventional stacked structure. When the light-emitting element 1 has a reverse stacked structure, that is, when the light-emitting element 1 includes the cathode 25 and the anode 22 provided above the cathode 25, and between the cathode 25 and the anode 22, the electron functional layer 9, light-emitting layer 8, and hole functional layer 7 for instance are stacked sequentially on the cathode 25, the first region in the cross section of the light-emitting layer 8, which is a region closer to the electron functional layer 9 than to the hole functional layer 7, includes the medium region 18 of metal sulfide (e.g., ZnS) more widely than the second region in the cross section of the light-emitting layer 8, which is a region closer to the hole functional layer 7 than to the electron functional layer 9.

A conceivable reason why such a difference in signal intensity occurs is that a relatively large difference in surface energy occurs between the portion A and portion B of the light-emitting layer 8 due to the influence of the thickness of the light-emitting layer 8 during the formation of the light-emitting layer 8. Thus, for example, forming the light-emitting layer 8 by laminating thin films multiple times can prevent such a difference in signal intensity as described above.

As earlier described, the quantum dots included in the foregoing second region in the cross section of the light-emitting layer 8 includes a higher proportion of oxidized quantum dots than the quantum dots included in the foregoing first region in the cross section of the light-emitting layer 8, in which the medium region 18 of metal sulfide (e.g., ZnS) is formed more widely.

### Second Embodiment

The following describes a second embodiment of the present disclosure on the basis of FIG. 16. A display device 50 according to this embodiment is different from the light-emitting element 1 described in the first embodiment in that this display device includes the foregoing light-emitting element 1 according to the first embodiment. The others are the same as those described in the first embodiment. For convenience in description, components having the same functions as those of the components illustrated in the drawings related to the first embodiment will be denoted by the same signs, and their descriptions will be omitted.

FIG. 16 is a schematic cross-sectional view of the schematic configuration of the display device 50 according to the second embodiment.

As illustrated in FIG. 16, the display device 50 includes red light-emitting elements 1R, green light-emitting elements 1G, and blue light-emitting elements 1B.

The anode 22 is provided on a substrate 4 including thin-film transistor elements (not shown) so as to be electrically connected to the drain electrode (not shown) of a corresponding one of the thin-film transistor elements through a contact hole provided in an insulating film 21.

An edge cover 23 is provided so as to cover the individual ends of a plurality of anodes 22.

In this embodiment, the quantum dot solution QDS for forming a red light-emitting layer 8R is formed in a predetermined region on the substrate 4, that is, only onto the anodes 22 provided in the red light-emitting elements 1R, through ink-jet printing in the atmosphere; moreover, the quantum dot solution QDS for forming a green light-emitting layer 8G is formed in a predetermined region on the substrate 4, that is, only onto the anodes 22 provided in the green light-emitting elements 1G, through ink-jet printing in the atmosphere; moreover, the quantum dot solution QDS for forming a blue light-emitting layer 8B is formed in a predetermined region on the substrate 4, that is, only onto the anodes 22 provided in the blue light-emitting elements 1B, through ink-jet printing in the atmosphere. Although this embodiment describes, by way of example, firstly forming the quantum dot solution QDS for forming the red light-emitting layer 8R, followed by the quantum dot solution QDS for forming the green light-emitting layer 8G, followed by the quantum dot solution QDS for forming the blue light-emitting layer 8B, these quantum dot solutions QDS may be formed in any order.

This embodiment describes, by way of example, forming each of the red light-emitting layer 8R, green light-emitting layer 8G, and blue light-emitting layer 8B in the same manner as that in the foregoing light-emitting layer 8 according to the first embodiment, with the exception that these layers are applied through ink-jet printing. It is noted that after the formation of the red light-emitting layer 8R, green light-emitting layer 8G, and blue light-emitting layer 8B in their respective predetermined regions through ink-jet printing, the red light-emitting layer 8R, green light-emitting layer 8G, and blue light-emitting layer 8B may undergo simultaneous one-time heating (baking). For example, after the formation of the red light-emitting layer 8R in a predetermined region through ink-jet printing, the red light-emitting layer 8R may undergo the first heating (baking), then after the formation of the green light-emitting layer 8G in a predetermined region through ink-jet printing, the red light-emitting layer 8R and green light-emitting layer 8G may undergo the second heating (baking), and then after the formation of the blue light-emitting layer 8B through ink-jet printing, the red light-emitting layer 8R, green light-emitting layer 8G, and blue light-emitting layer 8B may undergo the third heating (baking). Further, at least one of the red light-emitting layer 8R, green light-emitting layer 8G, and blue light-emitting layer 8B may be applied through ink-jet printing and formed in the same manner as that in the foregoing light-emitting layer 8 according to the first embodiment.

The display device 50 can prevent quantum dot's deterioration, and can further prevent both large rise in emission voltage and unnecessary current flowing between the QDs, thereby preventing the light-emitting layers from reduction in their emission characteristics.

### Third Embodiment

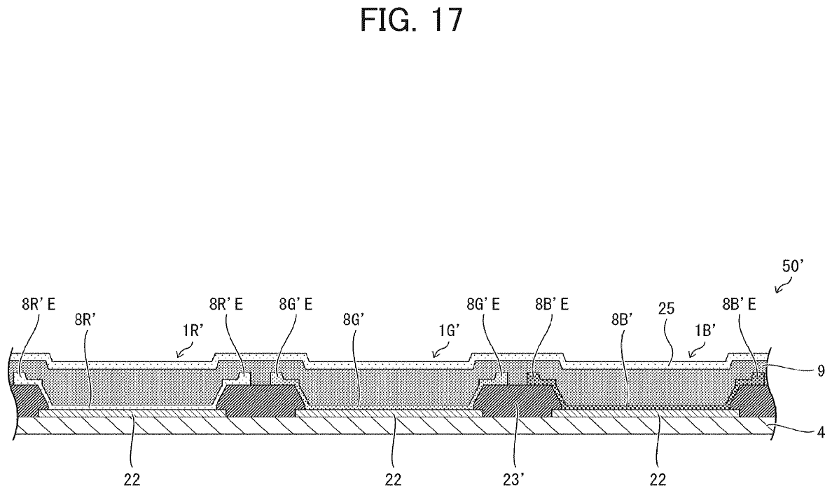

The following describes a third embodiment of the present disclosure on the basis of FIG. 17. A display device 50′ according to this embodiment is different from the display device 50 described in the second embodiment in that the display device 50′ includes light-emitting layers formed through liftoff using a resist layer or a water-repellent resist layer. The others are the same as those described in the second embodiment. For convenience in description, components having the same functions as those of the components illustrated in the drawings related to the second embodiment will be denoted by the same signs, and their descriptions will be omitted.

FIG. 17 is a schematic cross-sectional view of the schematic configuration of the display device 50′ according to the third embodiment.

As illustrated in FIG. 17, the display device 50′ includes red light-emitting elements 1R′, green light-emitting elements 1G′, and blue light-emitting elements 1B′.

The anode 22 is provided on the substrate 4 including thin-film transistor elements (not shown), and an edge cover 23′ is provided so as to cover the individual ends of a plurality of anodes 22.

In this embodiment, through patterning in the atmosphere, a red light-emitting layer 8R′ is formed in a predetermined region on the substrate 4, that is, onto the anodes 22 provided in the red light-emitting elements 1R′ and onto a part of the edge cover 23′ covering the ends of the anodes 22 provided in the red light-emitting elements 1R′; moreover, through patterning in the atmosphere, a green light-emitting layer 8G′ is formed in a predetermined region on the substrate 4, that is, onto the anodes 22 provided in the green light-emitting elements 1G′ and onto a part of the edge cover 23′ covering the ends of the anodes 22 provided in the green light-emitting elements 1G′; moreover, through patterning in the atmosphere, a blue light-emitting layer 8B′ is formed in a predetermined region on the substrate 4, that is, onto the anodes 22 provided in the blue light-emitting elements 1B′ and onto a part of the edge cover 23′ covering the ends of the anodes 22 provided in the blue light-emitting elements 1B′. Although this embodiment describes, by way of example, firstly forming the red light-emitting layer 8R′ through patterning, followed by the green light-emitting layer 8G′ through patterning, followed by the blue light-emitting layer 8B′ through patterning, these light-emitting layers may be formed through patterning in any order.

Each of the red light-emitting layer 8R′ green light-emitting layer 8G′, and blue light-emitting layer 8B′ can be formed through liftoff using a resist layer.

An example step of forming the red light-emitting layer 8R′ through liftoff using a resist layer includes the following: a resist-layer formation step of forming a resist layer having an opening overlapping, in plan view, a predetermined region on the substrate 4, that is, the anode 22 provided in the red light-emitting element 1R′ and a part of the edge cover 23′ covering the end of the anode 22 provided in the red light-emitting element 1R′; a step of applying the quantum dot solution QDS for forming the red light-emitting layer 8R′ onto the resist layer and into the opening after the resist-layer formation step; and a resist-layer peel step of peeling, after a step of drying the applied quantum dot solution QDS, a quantum dot layer formed from the quantum dot solution QDS on the resist layer. It is noted that the step of forming the green light-emitting layer 8G′ through liftoff using a resist layer, and the step of forming the blue light-emitting layer 8B′ through liftoff using a resist layer can be performed in a manner similar to that in the foregoing step of forming the red light-emitting layer 8R′ through liftoff using the resist layer.

In a modification of this embodiment, each of the red light-emitting layer 8R′, green light-emitting layer 8G′, and blue light-emitting layer 8B′ may be formed through liftoff using a water-repellent resist layer.

An example step of forming the red light-emitting layer 8R′ through liftoff using a water-repellent resist layer includes the following: a water-repellent-resist-layer formation step of forming a water-repellent resist layer having an opening overlapping, in plan view, a predetermined region on the substrate 4, that is, the anode 22 provided in the red light-emitting element 1R′ and a part of the edge cover 23′ covering the end of the anode 22 provided in the red light-emitting element 1R′; a step of applying the quantum dot solution QDS for forming the red light-emitting layer 8R′ onto the water-repellent resist layer and into the opening after the water-repellent-resist-layer formation step; and a water-repellent-resist-layer peel step of peeling the water-repellent resist layer after a step of drying the applied quantum dot solution QDS. It is noted that the step of forming the green light-emitting layer 8G′ through liftoff using a water-repellent resist layer, and the step of forming the blue light-emitting layer 8B′ through liftoff using a water-repellent resist layer can be performed in a manner similar to that in the foregoing step of forming the red light-emitting layer 8R′ through liftoff using the water-repellent resist layer.

As illustrated in FIG. 17, when each of the red light-emitting layer 8R′, green light-emitting layer 8G′, and blue light-emitting layer 8B′ is formed through liftoff using a normal resist layer or a water-repellent resist layer, a portion that comes into contact with a normal resist layer or water-repellent resist layer is formed thicker than the other portions, thereby forming a stepped portion 8R′E in the red light-emitting layer 8R′, a stepped portion 8G′E in the green light-emitting layer 8G′, and a stepped portion 8B′E in the blue light-emitting layer 8B′.

This embodiment describes, by way of example, an instance where each of the red light-emitting layer 8R′, green light-emitting layer 8R′, and blue light-emitting layer is formed in the same manner as that in the foregoing light-emitting layer 8 according to the first embodiment, with the exception that these layers are each formed through liftoff using a resist layer or a water-repellent resist layer. It is noted that after the formation of each of the red light-emitting layer 8R′, green light-emitting layer 8G′, and blue light-emitting layer 8B′ through patterning, the red light-emitting layer 8R′, green light-emitting layer 8G′, and blue light-emitting layer 8B′ may undergo simultaneous one-time heating (baking). For example, after the formation of the red light-emitting layer 8R′ through patterning, the red light-emitting layer 8R′ may undergo the first heating (baking), then after the formation of the green light-emitting layer 8G′ through patterning, the red light-emitting layer 8R′ and green light-emitting layer 8G′ may undergo the second heating (baking), and then after the formation of the blue light-emitting layer 8B′ through patterning, the red light-emitting layer 8R′, green light-emitting layer 8G′, and blue light-emitting layer 8B′ may undergo the third heating (baking). Further, at least one of the red light-emitting layer 8R′, green light-emitting layer 8G′, and blue light-emitting layer 8B′ may be formed through liftoff using a resist layer or a water-repellent resist layer, and formed in the same manner as that in the foregoing light-emitting layer 8 according to the first embodiment.

The display device 50′ can prevent quantum dot's deterioration, and can further prevent both large rise in emission voltage and unnecessary current flowing between the QDs, thereby preventing the light-emitting layers from reduction in their emission characteristics.

### Additional Note

The present disclosure is not limited to the foregoing embodiments. Various modifications can be made within the scope of the claims. An embodiment that is obtained in combination as appropriate with the technical means disclosed in the respective embodiments is also encompassed within the technical scope of the present disclosure. Furthermore, combining the technical means disclosed in the respective embodiments can form a new technical feature.

### INDUSTRIAL APPLICABILITY

The present disclosure can be used for a quantum dot solution, a light-emitting element, a display device, and a method for forming a light-emitting layer.

### REFERENCE SIGNS LIST

1 light-emitting element
1R, 1R′ red light-emitting element
1G, 1G′ green light-emitting element
1B, 1B′ blue light-emitting element
4 substrate
7 hole functional layer
8 light-emitting layer
8R, 8R′ red light-emitting layer
8G, 8G′ green light-emitting layer
8B, 8B′ blue light-emitting layer
8S1 first surface
8S2 second surface
9 electron functional layer
17 quantum dot
18 medium region containing inorganic material
18P metal sulfide precursor
21 insulating film
22 anode
23, 23′ edge cover
25 cathode
50, 50′ display device
QD1 first quantum dot
QD2 second quantum dot
QDU1, QDU2, QDU3 quantum dot unit
OL organic ligand
OL1 first organic ligand
OL2 second organic ligand
H1 first direction
H2 second direction
QDPR quantum-dot protection region
DIS dispersant
SOL solvent
QDS quantum dot solution

1. A quantum dot solution comprising:
a plurality of quantum dots;
a plurality of organic ligands other than a dithiocarboxylic acid;
a plurality of metal sulfide precursors having a total mass equal to or smaller than a total mass of the plurality of quantum dots and the plurality of organic ligands; and
a solvent.

2. The quantum dot solution according to claim 1, wherein the solvent comprises one or more selected from the group consisting of haloarenes in which a part of benzene's hydrogen is substituted with a halogen, and alkanes having 5 to 17 carbon atoms inclusive.

3. The quantum dot solution according to claim 1, wherein the solvent is a low-polarity solvent in which a square root of a square sum of a dipole term and a hydrogen bond term of a Hansen solubility parameter is 8.3 or less.

4. The quantum dot solution according to claim 1, wherein in the quantum dot solution in a unit volume, the total mass of the plurality of quantum dots and the plurality of organic ligands is 1.0 to 12.9 times inclusive of the total mass of the plurality of metal sulfide precursors.

5. The quantum dot solution according to claim 1, wherein in the quantum dot solution in a unit volume, a total mass of metal elements within the plurality of metal sulfide precursors is 5 to 20% inclusive of the total mass of the plurality of quantum dots and the plurality of organic ligands.

6. The quantum dot solution according to claim 1, wherein in the quantum dot solution in a unit volume, a total mass of inorganic components within the plurality of metal sulfide precursors is 5 to 63% inclusive of the total mass of the plurality of quantum dots and the plurality of organic ligands.

7. The quantum dot solution according to claim 1, wherein the plurality of metal sulfide precursors contains a dithiocarboxylic acid and a metal element.

8. The quantum dot solution according to claim 7, wherein the plurality of metal sulfide precursors is zinc xanthate or zinc dithiocarboxylate.

9. The quantum dot solution according to claim 1, wherein the quantum dot solution in a unit volume contains a dispersant having a smaller mass than the total mass of the plurality of metal sulfide precursors.

10. The quantum dot solution according to claim 9, wherein the dispersant is an amine or a pyridine.

11. (canceled)

12. The quantum dot solution according to claim 1, wherein in the quantum dot solution in a unit volume, a total mass of the plurality of organic ligands is 10 to 50% inclusive of a total mass of the plurality of quantum dots.

13. A light-emitting element comprising:
an anode;
a cathode; and
a light-emitting layer provided between the anode and the cathode,
wherein the light-emitting layer includes a plurality of quantum dot units including
a plurality of first organic ligands,
a plurality of second organic ligands, and
a first quantum dot and a second quantum dot disposed adjacently in a second direction orthogonal to a first direction that is a thickness direction of the light-emitting layer, and
wherein each of the plurality of quantum dot units disposed between a first surface facing the cathode of the light-emitting layer and a second surface facing the anode of the light-emitting layer includes a quantum-dot protection region including the plurality of first organic ligands closer to the first quantum dot than to the second quantum dot, the plurality of second organic ligands closer to the second quantum dot than to the first quantum dot, and a medium region provided at least between the plurality of first organic ligands and the plurality of second organic ligands, and containing an inorganic material.

14-16. (canceled)

17. The light-emitting element according to claim 13, wherein the medium region is amorphous.

18. The light-emitting element according to claim 13, wherein a total mass of the plurality of first organic ligands and the plurality of second organic ligands included in the light-emitting layer is 10 to 50% inclusive of a total mass of a plurality of the first quantum dots and a plurality of the second quantum dots included in the light-emitting layer.

19. The light-emitting element according to claim 13, wherein in one or more of the plurality of quantum dot units in a cross section of the light-emitting layer, a width of the medium region in the second direction of the light-emitting layer is smaller than a radius of the first quantum dot and a radius of the second quantum dot.

20. The light-emitting element according to claim 19, wherein in the one or more of the plurality of quantum dot units in the cross section of the light-emitting layer, the width of the medium region in the second direction of the light-emitting layer is 4 to 12% inclusive of the radius of the first quantum dot or the radius of the second quantum dot.

21. The light-emitting element according to claim 13, wherein
the medium regions of one or more of the plurality of quantum dot units constitute a part of the first surface, and
the medium regions of another one or more of the plurality of quantum dot units constitute a part of the second surface.

22. (canceled)

23. The light-emitting element according to claim 13, comprising:
a hole functional layer provided between the anode and the light-emitting layer; and
an electron functional layer provided between the cathode and the light-emitting layer,
wherein the electron functional layer, the light-emitting layer, the hole functional layer, and the anode are stacked on the cathode in a stated order, and
the medium region is formed more widely in a first region in a cross section of the light-emitting layer than in a second region in the cross section of the light-emitting layer, the first region being closer to the electron functional layer than to the hole functional layer, the second region being closer to the hole functional layer than to the electron functional layer.

24. (canceled)

25. The light-emitting element according to claim 23, wherein a plurality of the first quantum dots and a plurality of the second quantum dots included in the second region include a higher proportion of oxidized quantum dots than a plurality of the first quantum dots and a plurality of the second quantum dots included in the first region.

26. A display device comprising the light-emitting element according to claim 13.

27-33. (canceled)
